(19) United States
(12) Patent Application Publication
(10) Pub. No.: US 2011/0084735 A1
(43) Pub. Date: Apr. 14, 2011

(54) SCART INTERFACE CONTROL CIRCUIT AND VIDEO DEVICE USING THE SAME

(75) Inventors: JUN-BO WANG, Shenzhen City (CN); JUN-KAI WEI, Tu-Cheng (TW)

(73) Assignees: HONG FU JIN PRECISION INDUSTRY (ShenZhen) CO., LTD., Shenzhen City (CN); HON HAI PRECISION INDUSTRY CO., LTD., Tu-Cheng (TW)

(21) Appl. No.: 12/625,769

(22) Filed: Nov. 25, 2009

(30) Foreign Application Priority Data
Oct. 8, 2009 (CN) 200920312093.6

(51) Int. Cl. H03B 1/00

(52) U.S. Cl. 327/108

(57) ABSTRACT

A SCART interface control circuit outputs a mode switch signal to a switch signal pin of the SCART interface according to standby, widescreen and normal modes of video signals. The SCART interface control circuit comprises a first voltage circuit, a second voltage circuit, a voltage combination circuit and an amplifier circuit. The first and second voltage circuits output first and second voltage signals according to the video signal modes, respectively. The voltage combination circuit combines the first and second voltage signals into a combination voltage signal. The amplifier circuit amplifies the combination voltage signal so as to output the mode switch signal for indicating the video signal modes.

### BACKGROUND

1. Technical Field

Embodiments of the present disclosure relate to a SCART interface control circuit and a video device using the same.

2. Description of Related Art

In Europe, SCART interfaces have become standard interfaces for video devices, such as digital versatile discs (DVD), set-top-boxes (STB) and others. The eighth pin of the SCART interface is configured as a switch signal pin and carries a direct current (DC) voltage signal to indicate a present video signal mode. For example, 0V-2V means no video signals output, which is also known as a standby mode. 4.5V-7V means the video signals output in a widescreen (16:9) mode. 9.5V-12V means the video signals output in a normal (4:3) mode. Display devices detect the DC voltage signal carried by the switch signal pin of the SCART interface to identify the present video signal mode, and control processing circuits to display the video signals properly.

Customarily, the video devices utilize special chips to generate mode switch signals to the switch signal pin, which increases product cost. In addition, each display device has a particular impedance, which will inevitably cause a load effect when the display device is connected to the SCART interface. If the impedance of the display device is not appropriate, the load effect will become significant and bring an offset to the DC voltage of the switch signal pin of the SCART interface. Therefore, the display devices fail to realize the video signal modes and display the video signals improperly.

### BRIEF DESCRIPTION OF THE DRAWINGS

Many aspects of the embodiments can be better understood with references to the following drawings, wherein like numerals depict like parts, and wherein:

FIG. 1 is a block diagram of a video device of one embodiment of the present disclosure;

FIG. 2 is a detailed circuit diagram of a SCART interface control circuit according to one embodiment of the present disclosure;

FIG. 3 is a detailed circuit diagram of another embodiment of the SCART interface control circuit in FIG. 2;

FIG. 4 is a detailed circuit diagram of a SCART interface control circuit according to another embodiment of the present disclosure.

### DETAILED DESCRIPTION

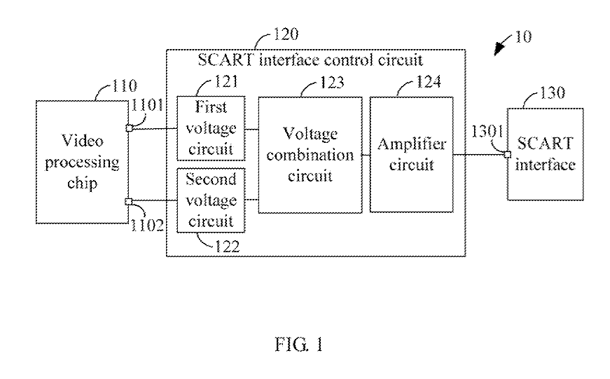

Referring to FIG. 1, a block diagram of one embodiment of a video device of the present disclosure is shown. In this embodiment, the video device 10 comprises a video processing chip 110, a SCART interface control circuit 120 and a SCART interface 130.

The video processing chip 110 generates video signals in standby, widescreen and normal modes, and comprises a first general purpose input/output (GPIO) pin 1101 and a second GPIO pin 1102. At least one of the first and second GPIO pins 1101 and 1102 generates different voltage signals, such as a high level signal, a low level signal and a high impedance signal, according to the video signal modes of the video processing chip 110. In one embodiment, the high level signal means a 3.3V voltage signal, the low level signal means a 0V voltage signal, and the high impedance signal can be seen as an open-circuit, but the disclosure is not limited thereto.

The SCART interface control circuit 120 is connected between the video processing chip 110 and the SCART interface 130, and generates a mode switch signal to a switch signal pin 1301 of the SCART interface 130 to indicate the video signal modes. The SCART interface control circuit 120 comprises a first voltage circuit 121, a second voltage circuit 122, a voltage combination circuit 123 and an amplifier circuit 124. The first voltage circuit 121 and the second voltage circuit 122 generate a first voltage signal and a second voltage signal according to the video signal modes, respectively. The voltage combination circuit 123 combines the first and second voltage signals into a combination voltage signal. The amplifier circuit 124 amplifies the combination voltage signal to the mode switch signal, subsequently outputs the mode switch signal to the switch pin 1301 of the SCART interface 130 to indicate the video signal modes.

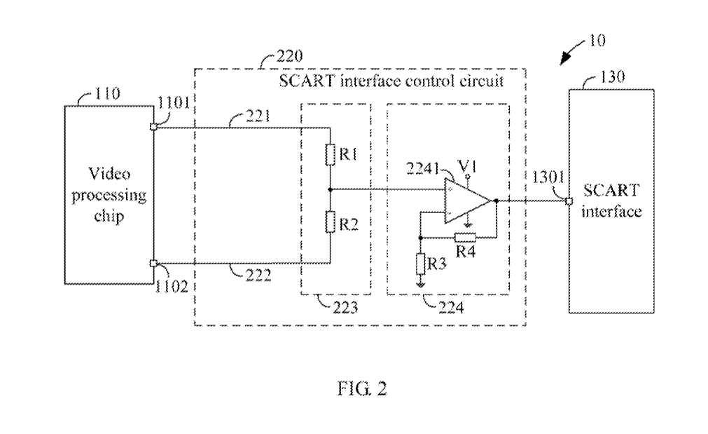

Referring to FIG. 2, a detailed circuit diagram of one embodiment of a SCART interface control circuit 220 of the present disclosure is shown. In this embodiment, The SCART interface control circuit 220 comprises a first voltage circuit 221, a second voltage circuit 222, a voltage combination circuit 223 and an amplifier circuit 224. Both the first voltage circuit 221 and the second voltage circuit 222 are formed of transmission lines. The first voltage circuit 221 is connected to the first GPIO pin 1101, and generates the first voltage signal according to the output of the first GPIO pin 1101. The second voltage circuit 222 is connected to the second GPIO pin 1102, and generates the second voltage signal according to the output of the second GPIO pin 1102. The voltage combination circuit 223 comprises two resistors R1 and R2. The two resistors R1 and R2 are connected between the first and second voltage circuits 221 and 222 in series, and a junction of the two resistors R1 and R2 is connected to an input of the amplifier circuit 224. In this embodiment, the two resistors R1 and R2 have the same resistance. In alternative embodiments, the impedance of the two resistors R1 and R2 are configured in certain proportions to meet practical requirements. The amplifier circuit 234 comprises an amplifier 2241, resistors R3 and R4. The non-inverting input of the amplifier 2241 is configured as the input of the amplifier circuit 234. The resistor R3 is connected between the inverting input of the amplifier 2241 and ground. The resistor R4 is connected between the inverting input and output of the amplifier 2241.

In this embodiment, the first and second GPIO pins 1101 and 1102 of the video processing chip 110 generate the low level and high level signals according to the video signal modes of the video processing chip 110. The first and second voltage circuits 221 and 222 transmit the output of the first and second GPIO pins 1101 and 1102 as the first and second voltage signals to the voltage combination circuit 223, respectively. The voltage combination circuit 223 combines the first and second voltage signals so as to output the combination voltage signal to the amplifier circuit 224.

In this embodiment, when the video signals are output in the standby mode, both the first and second GPIO pins 1101 and 1102 generate the low level signal, thus voltage of the combination voltage signal is 0V. When the video signals are output in the widescreen mode, the first GPIO pin 1101 generates the high level signal and the second GPIO pin 1102 generates the low level signal, thus the voltage of the combination voltage signal is 1.65V. When the video signals are output in the normal mode, both the first and second GPIO pins 1101 and 1102 generate the high level signal, thus the voltage of the combination voltage signal is 3.3V. In alternative embodiments, the voltages of the combination voltage signal corresponding to the standby, widescreen and normal modes are determined by the proportion of the two resistors R1 and R2 of the voltage combination circuit 223.

The amplifier circuit 224 receives and amplifies the combination voltage signal output by the voltage combination circuit 223 to the mode switch signal in accordance with the SCART standard, and subsequently outputs the mode switch signal to the switch signal pin 1301 of the SCART interface 130. Referring to the SCART standard, voltage ranges of the mode switch signal according to the standby, widescreen and normal modes are 0V-2V, 4.5V-7V and 9.5V-12V, respectively. Accordingly, voltage ranges of the amplified combination voltage signal also known as the mode switch signal output by the amplifier circuit 224 corresponding to the standby, widescreen and normal modes are 0V-2V, 4.5V-7V and 9.5V-12V, respectively.

The switch signal pin 1301 of the SCART interface 130 receives the mode switch signal output by the amplifier circuit 224, display devices subsequently detect the voltage of the mode switch signal and display the video signals properly. In the embodiment, the amplifier 2241 with high input impedance and low output impedance avoids the load effect of the display devices. Therefore, the mode switch signal output by the amplifier 2241 of the amplifier circuit 224 maintains stability.

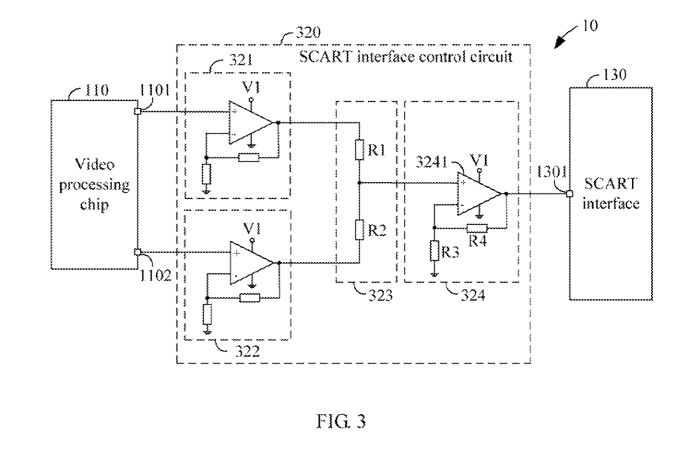

Referring to FIG. 3, a detailed circuit diagram of another embodiment of a SCART interface control circuit 320 is shown, differing from the SCART interface control circuit 220 of FIG. 2 only in a first voltage circuit 321 and a second voltage circuit 322. In this embodiment, each of the first voltage circuit 321 and the second voltage circuit 322 comprises a non-inverting amplifier to amplify the output of the first GPIO pin 1101 and the second GPIO pin 1102 of the video processing chip 110, respectively. The non-inverting amplifiers of the first voltage circuit 321 and the second voltage circuit 322 have the same amplification coefficient, and are configured in common use. Consequently, amplification coefficient of an amplifier circuit 324 of the SCART interface control circuit is adjusted according to the amplification coefficient of the first voltage circuit 321 and the second voltage circuit 322, to ensure that the voltage ranges of the mode switch signal output by the amplifier circuit 324 corresponding to the standby, widescreen and normal modes are 0-2V, 4.5-7V and 9.5-12V, respectively.

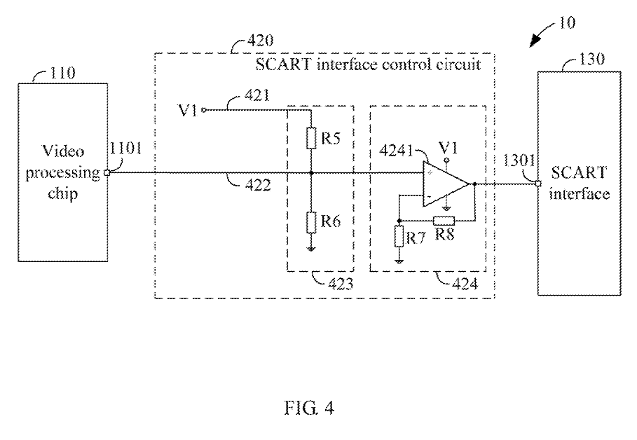

Referring to FIG. 4, a detailed circuit diagram of a SCART interface control circuit 420 of one embodiment of the present disclosure is shown. In this embodiment, the SCART interface control circuit 420 comprises a first voltage circuit 421, a second voltage circuit 422, a voltage combination circuit 423 and an amplifier circuit 424. Both the first voltage circuit 421 and the second voltage circuit 422 are formed of the transmission lines. The first voltage circuit 421 is connected to a reference voltage, and generates the first voltage signal according to the reference voltage signal. The second voltage circuit 422 is connected to the GPIO pin 1101, and generates the second voltage signal according to an output of the GPIO pin 1101. The voltage combination circuit 423 comprises resistors R5 and R6. The resistor R5 comprises one end connected to the first voltage circuit 421, and the other end connected to the amplifier circuit 224. The resistor R6 comprises one end connected to the second voltage circuit 422 and the amplifier circuit 424, and the other end grounded. In this embodiment, the resistors R5 and R6 have the same resistance. In alternative embodiments, the impedance of the resistor R5 and R6 are configured in certain proportions to meet practice requirements. The amplifier circuit 424 comprises an amplifier 4241, and resistors R7 and R8. The non-inverting input of the amplifier 4241 is configured as the input of the amplifier circuit 424. The resistor R7 is connected between the inverting input of the amplifier 4241 and ground. The resistor R8 is connected between the inverting input and output of the amplifier 4241.

The first voltage circuit 421 and the second voltage circuit 422 transmit the reference voltage signal and the output of the GPIO pin 1101 as the first and second voltage signals to the voltage combination circuit 423, respectively. In this embodiment, the reference voltage is about 3.3V. The GPIO pin 1101 of the video processing chip 110 generates the low level, high impedance and high level signals according to the standby, widescreen and normal modes, respectively.

The voltage combination circuit 423 combines the first and second voltage signals to output the combination voltage signal to the amplifier circuit 424. In this embodiment, when the video signals are output in the standby mode, the GPIO pin 1101 generates the low level signal, thus the voltage of the combination voltage signal is 0V. When the video signals are output in the widescreen mode, the GPIO pin 1101 generates the high impedance signal, thus the voltage of the combination voltage signal is 1.65V. When the video signal modes is output in the normal mode, the GPIO pin 1101 generates the high level signal, thus the voltage of the combination voltage signal is 3.3V. In alternative embodiments, the voltages of the combination voltage signal corresponding to the standby, widescreen and normal modes can be determined by the proportion of the resistors R5 and R6 of the voltage combination circuit 423.

The amplifier circuit 424 receives and amplifies the combination voltage signal from the voltage combination circuit 423 to the mode switch signal in accordance with the SCART standard, and output the mode switch signal to the switch signal pin 1301 of the SCART interface 130 to indicate the video signal modes. Referring to the SCART standard, the voltage ranges of the mode switch signal according to the standby, widescreen and normal modes are 0V-2V, 4.5V-7V and 9.5V-12V, respectively. Accordingly, the voltage ranges of the amplified combination voltage signal also known as the mode switch signal corresponding to the standby, widescreen and normal modes output by the amplifier circuit 224 are 0V-2V, 4.5V-7V and 9.5V-12V, respectively.

The switch signal pin 1301 of the SCART interface 130 receives the mode switch signal output by the amplifier circuit 424, and the display devices detect the voltage of the mode switch signal and process the video signals properly. In the embodiments, because the high input impedance and low output impedance of the amplifier 4241 avoid load effect of the display devices, the mode switch signal output by the amplifier 4241 of the amplifier circuit 224 is operable to maintain stability.

It is apparent that embodiments of the present disclosure provide a SCART interface control circuit and a video device using the same operable to utilize an amplifier circuit with high input impedance and low output impedance to output a mode switch signal to a switch signal pin of the SCART interface. Therefore, load effect of display devices is avoided and cost of the video devices decreases.

While the present disclosure has been described in combination with embodiments thereof, it is evident that many alternatives, modifications, and variations will be apparent to those skilled in the art in light of the foregoing description. Accordingly, it is intended to embrace all such alternatives, modifications, and variations as fall within the spirit and scope of the appended claims.

What is claimed is:

1. A SCART interface control circuit connected between a video processing chip and a SCART interface to output a mode switch signal to a switch signal pin of the SCART interface to indicate standby, widescreen and normal modes of video signals, wherein the video processing chip comprises first and second general purpose input/output (GPIO) pins to output high and low level signals according the video signal modes, the SCART interface control circuit comprising:
a first voltage circuit connected to the first GPIO pin, to output a first voltage signal according to the output of the first GPIO pin;
a second voltage circuit connected to the second GPIO pin, to output a second voltage signal according to the output of the second GPIO pin;
a voltage combination circuit to combine the first and second voltage signals into a combination voltage signal;
an amplifier circuit to amplify the combination voltage signal so as to output the mode switch signal for indicating the video signal modes.

2. The SCART interface control circuit as claimed in claim 1, wherein both the first and second GPIO pins output the low level signal in the standby mode, the first GPIO pin outputs the high level signal and the second GPIO pin outputs the low level signal in the widescreen mode, both the first and second GPIO pins output the high level signal in the normal mode.

3. The SCART interface control circuit as claimed in claim 2, wherein the first and second voltage circuits are formed of transmission lines and transmit the output of the first and second GPIO pins as the first and second voltage signals to the voltage combination circuit, respectively.

4. The SCART interface control circuit as claimed in claim 2, wherein both the first and second voltage circuits comprise a non-inverting amplifier to amplify the output of the first and second GPIO pins, respectively.

5. The SCART interface control circuit as claimed in claim 1, wherein the voltage combination circuit comprises two resistors connected between the first and second voltage circuits in series, wherein a junction of the two resistors is connected to the amplifier circuit.

6. A SCART interface control circuit connected between a video processing chip and a SCART interface to output a mode switch signal to a switch signal pin of the SCART interface to indicate standby, widescreen and normal modes of video signals, wherein the video processing chip comprises a GPIO pin to output high impedance, high or low level signals according the video signal modes, the SCART interface control circuit comprising:
a first voltage circuit connected to a reference voltage to output the first voltage signal according to the reference voltage;
a second voltage circuit connected to the GPIO pin to output a second voltage signal according to the output of the first GPIO pin;
a voltage combination circuit to combine the first and second voltage signals into a combination voltage signal;
an amplifier circuit to amplify the combination voltage signal so as to output the mode switch signal for indicating the video signal modes.

7. The SCART interface control circuit as claimed in claim 6, wherein the first GPIO pin outputs the low level, high impedance and high level signals according to the standby, widescreen and normal modes of the video signals, respectively.

8. The SCART interface control circuit as claimed in claim 7, wherein both the first and second voltage circuits are formed of transmission lines and transmit the output of the reference voltage and the GPIO pin as the first and second voltage signals to the voltage combination circuit, respectively.

9. The SCART interface control circuit as claimed in claim 6, wherein the voltage combination circuit comprises:
a first resistor comprising one end connected to the first voltage circuit, and the other end connected to the amplifier circuit; and
a second resistor comprising one end connected to the second voltage circuit and the amplifier circuit, the other end grounded.

10. A video device, comprising:
a video processing chip to output video signals in standby, widescreen and normal modes, comprising at least one GPIO pin to output high impedance, high or low level signals according the video signal modes;
a SCART interface comprising a switch signal pin;
a SCART interface control circuit connected between the video processing chip and the SCART interface to output a mode switch signal to the switch signal pin of the SCART interface to indicate the video signal modes of the video signals, the SCART interface control circuit comprising:
a first voltage circuit to output the first voltage signal according to alternative one of a reference voltage and the output of a first GPIO pin;
a second voltage circuit to output a second voltage signal according to the output of a second GPIO pin;
a voltage combination circuit to combine the first and second voltage signals into a combination voltage signal;
an amplifier circuit to amplify the combination voltage signal so as to output the mode switch signal for indicating the video signal modes.

11. The video device as claimed in claim 10, wherein both the first and second GPIO pins output the low level signal in the standby mode, the first GPIO pin outputs the high level signal and the second GPIO pin outputs the low level signal in the widescreen mode, the first and second GPIO pins output the high level signal in the normal mode.

12. The video device as claimed in claim 11, wherein the first and second voltage circuits are formed of transmission lines and transmit the output of the first and second GPIO pins as the first and second voltage signal to the voltage combination circuit, respectively.

13. The video device as claimed in claim 12, wherein both the first and second voltage circuits comprise a non-inverting amplifier and amplify the output of the first and second GPIO pins, respectively.

14. The video device as claimed in claim 11, wherein the voltage combination circuit comprises two resistors connected between the first and second voltage circuits in series, wherein a joint of the two resistors is connected to the amplifier circuit.

15. The video device as claimed in claim 10, wherein the reference voltage outputs the high level signal, the second GPIO pin outputs the low level, high impedance and high level signals in the standby, widescreen and normal modes, respectively.

16. The video device as claimed in claim 15, wherein the first and second voltage circuits are formed of transmission lines and transmit the output of the reference voltage and the second GPIO pin as the first and second voltage signals to the voltage combination circuit, respectively.

17. The video device as claimed in claim 16, wherein the voltage combination circuit comprises:
a first resistor comprising one end connected to the first voltage circuit, and the other end connected to the amplifier circuit; and
a second resistor comprising one end connected to the second voltage circuit and the amplifier circuit, the other end grounded.
